(19) United States
(12) Patent Application Publication
(10) Pub. No.: US 2020/0352034 A1
(43) Pub. Date: Nov. 5, 2020

(54) Methods for Manufacturing Electronic Devices

(71) Applicant: Infineon Technologies AG, Neubiberg (DE)

(72) Inventors: Thomas Bemmerl, Schwandorf (DE); Joachim Mahler, Regensburg (DE)

(21) Appl. No.: 16/932,925

(22) Filed: Jul. 20, 2020

Related U.S. Application Data
(62) Division of application No. 15/982,778, filed on May 17, 2018.

(30) Foreign Application Priority Data
May 19, 2017 (DE) 102017208533.9

(51) Int. Cl. H05K 3/32; H01L 23/488; B22F 7/08; B22F 7/06; H05K 7/02

(52) U.S. Cl. CPC H05K 3/325; H01L 23/488; H05K 3/32; B22F 7/08; B22F 7/06; H05K 3/3484; H05K 3/321; H05K 2201/10234; H01L 2224/83192; H01L 2224/73221; H05K 7/02

(57) ABSTRACT

A method includes providing a joining material between a surface of a component and a surface of an electronic component. A plurality of spacer elements is embedded in the joining material. The spacer elements are coated with a coating material. The coating material includes sinter particles. A dimension of the sinter particles is greater than 1 nanometer and smaller than 1000 nanometers. The method further includes forming interconnects from the coating material. The interconnects are arranged between the spacer elements and the surface of the component, and between the spacer elements and the surface of the electronic component.

### TECHNICAL FIELD

The present disclosure relates in general to electronics and semiconductor technology. More particular, the disclosure relates to joining materials, electronic devices and methods for manufacturing such electronic devices.

### BACKGROUND

Manufacturers of electronic devices are constantly striving to increase the performance and reliability of their products. The design and defined fabrication of connections between components of electronic devices may influence the thermal and electrical performance as well as the reliability of the devices. It may thus be desirable to provide joining materials that increase the performance and reliability of electronic devices. In addition, appropriate methods for applying the joining materials in the production of electronic devices need to be provided.

### SUMMARY

Various aspects pertain to a method including the following acts: providing a joining material between a surface of a component and a surface of an electronic component, wherein spacer elements are embedded in the joining material, wherein the spacer elements are coated with a coating material; and forming interconnects from the coating material, wherein the interconnects are arranged between the spacer elements and the surface of the component and between the spacer elements and the surface of the electronic component.

Various aspects pertain to a joining material, comprising: a base material; spacer elements embedded in the base material; a coating material, wherein the spacer elements are coated with the coating material.

Various aspects pertain to an electronic device, comprising: a component; an electronic component; a joining material arranged between a surface of the component and a surface of the electronic component, wherein spacer elements are embedded in the joining material; and interconnects arranged between the spacer elements and the surface of the component and between the spacer elements and the surface of the electronic component.

### BRIEF DESCRIPTION OF THE DRAWINGS

The accompanying drawings are included to provide a further understanding of aspects and are incorporated in and constitute a part of this specification. The drawings illustrate aspects and together with the description serve to explain principles of aspects. Other aspects and many of the intended advantages of aspects will be readily appreciated as they become better understood by reference to the following detailed description. The elements of the drawings are not necessarily to scale relative to each other. Like reference signs may designate corresponding similar parts.

FIG. 1 schematically illustrates a joining material 100 in accordance with the disclosure. The joining material 100 may be used in the production of electronic devices. In particular, the joining material may be used for the fabrication of interconnects in electronic devices.

FIGS. 2A and 2B schematically illustrate respective cross-sectional side views of a method for manufacturing an electronic device in accordance with the disclosure. The manufactured electronic device includes interconnects formed from a coating material that coats spacer elements in a joining material.

FIG. 3 schematically illustrates a cross-sectional side view of an electronic device in accordance with the disclosure. The electronic device may be manufactured based on the method of FIGS. 2A and 2B.

FIG. 4 schematically illustrates a cross-sectional side view of a spacer element coated with a coating material. The coating material includes a polymer covering the surface of the spacer element and particles embedded in the polymer.

FIG. 5 schematically illustrates a cross-sectional side view of a spacer element coated with a coating material. The coating material includes particles arranged on the periphery of the spacer element.

FIGS. 6A to 6D schematically illustrate respective cross-sectional side views of a method for manufacturing an electronic device in accordance with the disclosure. The method may be seen as a more detailed implementation of the method of FIGS. 2A and 2B.

FIG. 7 schematically illustrates a cross-sectional side view of an electronic device in accordance with the disclosure. The electronic device may be seen as a more specific implementation of the electronic device of FIG. 3. The electronic device exemplarily includes a semiconductor die joint to a leadframe.

FIG. 8 schematically illustrates a cross-sectional side view of an electronic device in accordance with the disclosure. The electronic device may be seen as a more specific implementation of the electronic device of FIG. 3. The electronic device exemplarily includes a metal clip joint to an electrical contact of a semiconductor chip.

### DETAILED DESCRIPTION

In the following detailed description, reference is made to the accompanying drawings, in which are shown by way of illustration specific aspects in which the disclosure may be practiced. In this regard, directional terminology, such as “top”, “bottom”, “front”, “back”, etc. may be used with reference to the orientation of the figures being described. Since components of described devices may be positioned in a number of different orientations, the directional terminology may be used for purposes of illustration and is in no way limiting. Other aspects may be utilized and structural or logical changes may be made without departing from the concept of the present disclosure. Hence, the following detailed description is not to be taken in a limiting sense, and the concept of the present disclosure is defined by the appended claims.

Different types of joining materials are described herein. In addition, methods and devices are described that may include or utilize such joining materials. In general, the term “joining material” may refer to any suitable material configured to join components together, i.e. to attach or fix the components to each another. Joining materials as described herein may particularly refer to a material that may be used in the field of electronics and semiconductor technology. A joining material may be used for joining a component to an electronic component and/or vice versa. In one example, the joining material may be used for attaching a semiconductor die to e.g. a diepad, a leadframe, a printed circuit board, etc. In a further example, the joining material may be used for attaching an active or passive electronic component to e.g. a board, a substrate, etc. In yet a further example, a joining material may be used for attaching a metal clip to e.g. an electrode of a semiconductor die, for example to a source electrode of a power semiconductor die. Further examples of joint components are possible, but not explicitly specified at this point for the sake of simplicity. Note that exemplary components and electronic components joint together are described below.

The joining material may include a material that may be referred to as a base material. The base material may be or may include at least one of a metal paste, a sinter paste, a solder paste, a nano paste. Metal pastes or sinter pastes may be sintered in e.g. a cure oven to remove an included binder and/or solvent and to densify an included metal material by reducing its porosity. For example, metal pastes or sinter pastes may include particles from at least one of copper, silver, nickel, palladium, gold, etc. In general, the metal or sinter particles may have a dimension (or diameter) lying in a range from about 1 nanometer to about 5 micrometers. In particular, the metal or sinter particles may have a dimension (or diameter) lying in a range from about 1 nanometer to about 1000 nanometers such that the pastes may be referred to as nano pastes. In a non-limiting example of manufacturing a sintered metal material, a copper paste including a binder and a plurality of copper nanoparticles may be provided. The metal paste may be heat treated in a non-oxidizing atmosphere at a peak temperature lying in a range from about 150 degrees Celsius to about 350 degrees Celsius, more particular from about 200 degrees Celsius to about 300 degrees Celsius, in order to remove the binder. A curing time may e.g. lie in a range from about 10 minutes to about 3 hours.

The base material of the joining material also may be or may include at least one an adhesive material, in particular a conductive adhesive. In one example, the joining material may be an adhesive paste, in particular a polymer based adhesive paste or an epoxy based adhesive paste. Unmodified polymer based adhesive pastes may be insulating or may exhibit low electrical and/or thermal conductivities. Appropriate filler particles may be used to provide conductive adhesive pastes with increased electrical and/or thermal conductivities. The filler particles may be added to form a network within the polymer matrix such that electrons and/or heat may flow across the particle contact points in order to make the mixture electrically and/or thermally conductive. The filler particles may e.g. include at least one of silver, copper, nickel, gold, aluminum, mixing systems thereof. The filler particles may also e.g. include at least one of silicon dioxide, aluminum oxide, alumina, boron nitride, silicon carbide, gallium nitride, mixing systems thereof. For the case of silver filler particles, the base material of the joining material may particularly include or may correspond to a silver conductive adhesive paste. The filler particles may have a dimension (or diameter) lying in a range from about 50 nanometers to about 10 micrometers.

Methods and devices as described herein may include or utilize components and electronic components. A component and an electronic component may be joint together by means of a joining material as previously described. In one example, a component may be configured to provide a mounting platform for an electronic component. In this regard, a component may include at least one of a lead or pin, a diepad, a leadframe, a substrate, a power electronic substrate, a board or printed circuit board, a carrier or chip carrier, a semiconductor package, etc. A leadframe may include leads, diepads and may be fabricated from metals and/or metal alloys, in particular at least one of copper, copper alloys, nickel, iron nickel, aluminum, aluminum alloys, steel, stainless steel, etc. A power electronic substrate may include an at least partially metal plated ceramic core material. For example, a power electronic substrate may correspond to a direct copper bonded substrate, an active metal brazed substrate, an insulated metal substrate, etc. In a further example, a component may be configured to provide an electrical coupling to an electronic component. In this regard, a component may include at least one of a metal clip, a pin or lead, etc.

An electronic component may include at least one of a passive electronic component, an active electronic component, a semiconductor die, a semiconductor package, a sensor, a light emitting diode (LED), etc. For example, a passive electronic component may include at least one of a resistor, a capacitor, an inductor, etc., and an active electronic component may include at least one of a diode, a transistor, an integrated circuit, an optoelectronic device, etc. A semiconductor die may include integrated circuits, passive electronic components, active electronic components, microelectromechanical structures, etc. The integrated circuits may be designed as logic integrated circuits, analog integrated circuits, mixed signal integrated circuits, power integrated circuits, etc.

Methods and devices as described herein may include or may utilize spacer elements. The spacer elements may be embedded in a joining material, more particular in the base material of the joining material as previously described. Accordingly, the spacer elements may be arranged between a component and an electronic component to be joined together. As such, the spacer elements may provide a defined distance or range between joint components. In particular, the spacer elements may be used to provide a bondline between a component and an electronic component, the bondline having a thickness that may be substantially constant and may substantially equal the dimension of the spacer elements.

In general, the spacer elements may be of arbitrary form or shape. In particular, the spacer elements may at least partially have a rounded form, i.e. ball-shaped, oval-shaped, drop-shaped, etc. In one example, the spacer elements may correspond to spacer balls. A dimension (or diameter) of the spacer elements may lie in a range from about 10 micrometer to about 80 micrometer, more particular in a range from about 10 micrometer to about 70 micrometer, more particular in a range from about 10 micrometer to about 60 micrometer, more particular in a range from about 10 micrometer to about 50 micrometer, more particular in a range from about 10 micrometer to about 40 micrometer, more particular in a range from about 10 micrometer to about 30 micrometer. In particular, the spacer elements embedded in a joining material may all be of a substantially similar dimension. For example, all spacer balls embedded in a joining material may have a similar diameter lying in one of the above-mentioned ranges.

The spacer elements may be made from at least one of a metal, a polymer, a metal coated polymer. Spacer elements including or made of a metal may e.g. include at least one of copper, silver, nickel, alloys thereof. Such spacer elements may increase a thermal and/or electrical conductivity of the joining material. For example, a conductivity of a solder joining material may be increased by embedding spacer balls made of copper. Spacer elements including or made from a polymer may provide an increased compressibility compared to spacer elements made from a metal. Polymeric spacer elements may be provided with a metal coating that may increase a conductivity of the spacer elements.

Methods and devices as described herein may include or utilize a coating material. The coating material may be configured to coat spacer elements, i.e. to at least partially cover the periphery of the spacer elements. Any suitable technique may be applied for coating the spacer elements. For example, coating the spacer elements with the coating material may include at least one of a spray coating, a deposition from a gas phase, a deposition from a liquid phase, a vapor-liquid-solid method.

The coating material may contribute to a formation of interconnects that may be arranged between spacer elements and a surface of a component or a surface of an electronic component. For example, such interconnects may be formed on the basis of a sintering process. In this regard, the interconnects may be at least partially formed from a coating material including a sinter material. Furthermore, the interconnects may be formed based on melting a coating material including a metal having a melting temperature lying in a range from about 150 degrees Celsius to about 1200 degrees Celsius. In general, the coating material may be configured to react with the material of a surface of a component or the surface of an electronic component when forming the interconnects. For example, such surfaces may include a metal or metal alloy as e.g. previously described for the case of the component being a leadframe. Accordingly, the formed interconnects may also include material from the respective surface of the component or electronic component. For example, the interconnects may include an intermetallic phase material (or intermetallic phases) that may particularly differ from the material of the respective surface.

The coating material may include sinter particles. The sinter particles may be made of or may include at least one of copper, silver, nickel, palladium, gold, etc. A sinter particle may have a dimension lying in a range from about 1 nanometer to about 1000 nanometers. That is, the sinter particles may correspond to nanoparticles or nano-sized structures. More particular, a dimension of a sinter particle may lie in a range from about 100 nanometers to about 1000 nanometers, more particular from about 50 nanometers to about 800 nanometers, more particular from about 50 nanometers to about 600 nanometers, more particular from about 50 nanometers to about 400 nanometers, more particular from about 50 nanometers to about 200 nanometers. Compared to a dimension of sinter particles that may be embedded in a joining material, a dimension of sinter particles included in a coating material may be smaller. In addition, a density of sinter particles in a coating material may be greater than a density of sinter particles in a joining material. In general, the sinter particles may be of arbitrary form or shape. In one example, the sinter particles may at least partially have a rounded form, i.e. ball-shaped, oval-shaped, drop-shaped, etc. In a further example, the sinter particles may correspond to nano-needles, i.e. conical or tubular needles in a nanometer size range. A nano-needle may have a length or longitudinal extent that may lie in one of the ranges given above for possible dimensions of a sinter particle.

In a first example, the sinter particles may be embedded in a polymer that may cover the surface of the spacer elements. For example, the polymer may include at least one of a polyvinyl alcohol, a polyimide, a polyamide, an acrylate resin, a thermoplast, a thermoset polymer, an epoxy, a high-performance polymer, etc. The polymer may at least partially volatilize or escape when forming the interconnects, for example during a sintering or heating process. In particular, the polymer may completely volatilize such that no polymer may remain in the sintered material. In a second example, the sinter particles may be directly arranged on the surfaces or peripheries of the spacer elements without an additional embedding material. That is, exposed surface parts of the spacer elements may be arranged between the sinter particles. Here, the sinter particles may cover from about 10% to about 100% of the overall surface of the spacer elements, more particular from about 30% to about 100%, more particular from about 50% to about 100%, more particular from about 70% to about 100%, more particular from about 90% to about 100%.

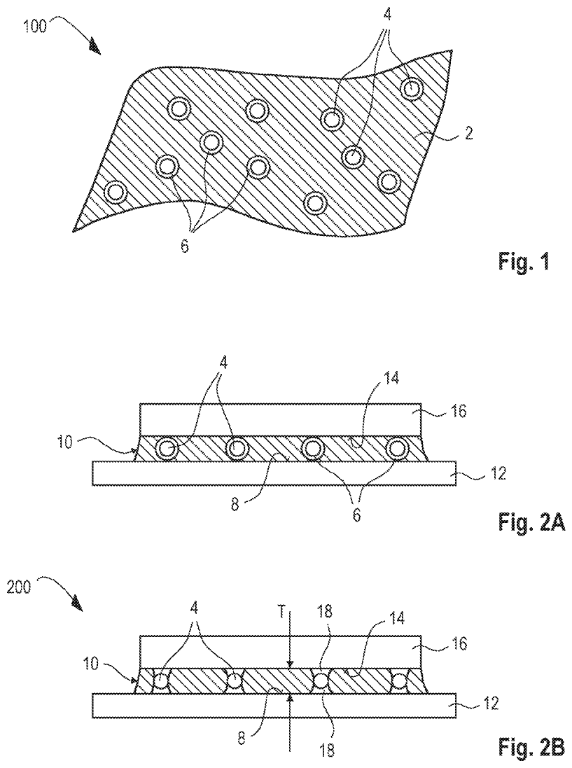

FIG. 1 schematically illustrates a joining material 100 in accordance with the disclosure. The joining material 100 is illustrated in a general manner in order to qualitatively specify aspects of the disclosure. The joining material 100 may be used for joining together a component and an electronic component. In this regard, the joining material 100 may be particularly used for the fabrication of interconnects in an electronic device as will be described later on.

The joining material 100 may include a base material 2 and spacer elements 4 embedded in the base material 2. In addition, the joining material 100 may include a coating material 6, wherein the spacer elements 4 may be coated with the coating material 6. Regarding properties of the joining material 100 and its components, reference is made to foregoing paragraphs in which related details have been discussed. Note that the illustration of FIG. 1 is exemplary and in no way limiting. For example, the spacer elements 4 are illustrated to be ball-shaped. In further examples, the spacer elements 4 may also be of different shape.

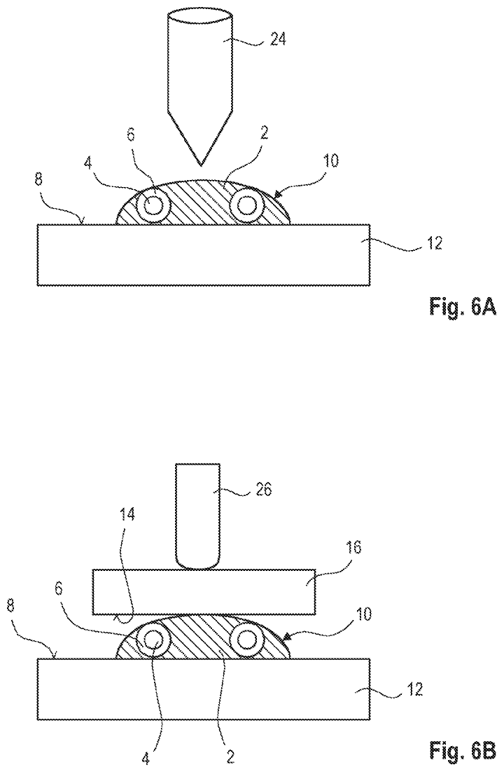

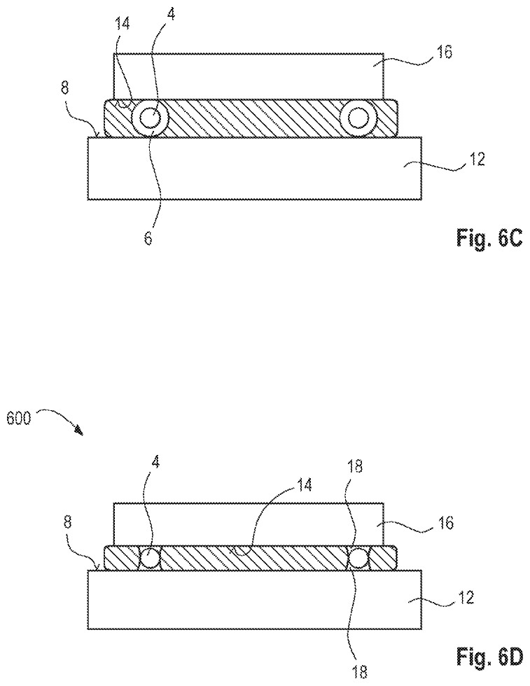

FIGS. 2A and 2B schematically illustrate respective cross-sectional side views of a method for manufacturing an electronic device 200 in accordance with the disclosure. The method of FIGS. 2A and 2B is illustrated in a general manner in order to qualitatively specify aspects of the disclosure. The method may include further acts which are not illustrated for the sake of simplicity. For example, the method may be extended by any of the aspects described in connection with the method of FIGS. 6A through 6D.

In FIG. 2A, a joining material 10 may be provided between a surface 8 of a component 12 and a surface 14 of an electronic component 16. Spacer elements 4 may be embedded in the joining material 10. The spacer elements 4 may be coated with a coating material 6. The joining material 10 may be similar to the joining material 100 of FIG. 1. The illustration of FIG. 2A is exemplary and in no way limiting. For example, FIG. 2A shows four spacer elements 4. It is understood that an actual number of spacer elements in the joining material may be orders of magnitude greater.

In FIG. 2B, interconnects 18 may be formed from the coating material 6. The interconnects 18 may be arranged between the spacer elements 4 and the surface 8 of the component 12. In addition, the interconnects 18 may be arranged between the spacer elements 4 and the surface 14 of the electronic component 16.

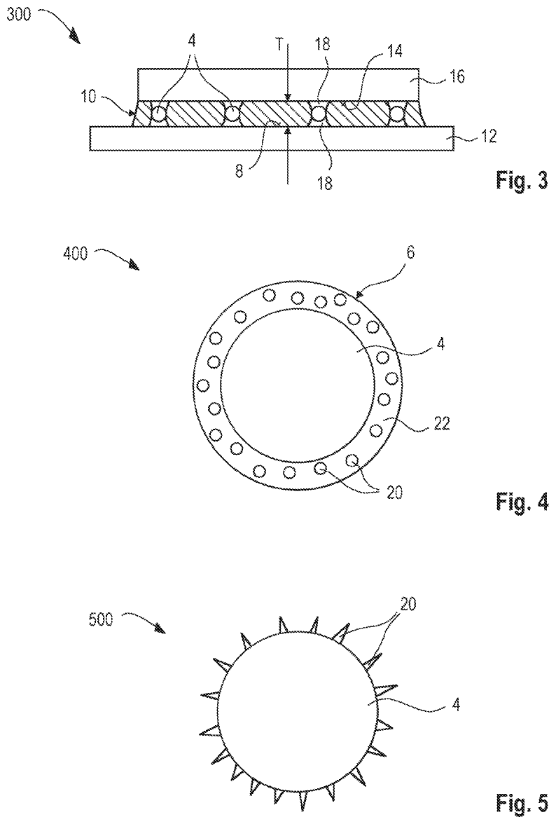

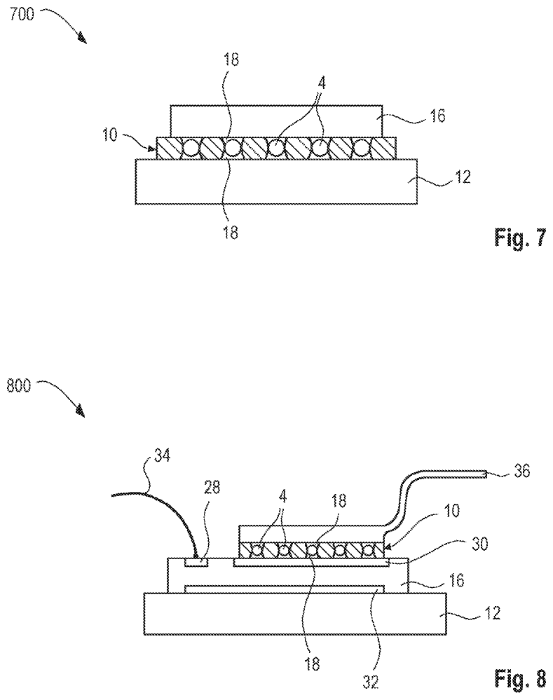

FIG. 3 schematically illustrates a cross-sectional side view of an electronic device 300 in accordance with the disclosure. The electronic device 300 is illustrated in a general manner in order to qualitatively specify aspects of the disclosure. The electronic device 300 may include further components which are not illustrated for the sake of simplicity. For example, the electronic device 300 may be extended by any of the aspects described in connection with FIGS. 7 and 8.

The electronic device 300 may include a component 12 and an electronic component 16. In addition, the electronic device 300 may include a joining material 10 arranged between a surface 8 of the component 12 and a surface 14 of the electronic component 16. Spacer elements 4 may be embedded in the joining material 10. Furthermore, interconnects 18 may be arranged between the spacer elements 4 and the surface 8 of the component 12 and between the spacer elements 4 and the surface 14 of the electronic component 16. The electronic device 300 may be similar to the electronic device 200 of FIG. 2B such that comments made in connection with FIGS. 2A and 2B may also hold true for FIG. 3 and vice versa.

The joining material 10 arranged between the component 12 and the electronic component 16 may represent or may be referred to as bondline. The spacer elements 4 may be chosen to have a substantially similar dimension. For example, for the exemplary case of ball-shaped spacer elements 4, the spacer elements 4 may have a substantially similar diameter. Furthermore, one layer of spacer elements 4 may be arranged in a horizontal direction between the component 12 and the electronic component 16, i.e. the spacer elements 4 may not be stacked over each other in the vertical direction. Accordingly, a thickness T of the bondline may be substantially constant and may substantially equal the dimension (or diameter) of the spacer elements 4. In this regard, it is to be understood that the thickness of the bondline may slightly vary due to unavoidable procedural inaccuracies.

The bondline thickness T may be kept in a defined range and may be controlled by choosing a corresponding dimension of the spacer elements 4. In this regard, a tilt of the electronic component 16 with respect to the component 12 may be substantially avoided, i.e. the surfaces 8 and 14 may be kept substantially parallel to each other. Due to a defined and substantially constant bondline thickness and a minor tilt, a defined thermal and electrical performance of the electronic device 300 including the joint components 12 and 16 may be supported. In addition, a thermal and electrical reliability of the electronic device 300 may be increased.

The interconnects 18 may represent material joint connections between the spacer elements 4 and the surfaces 8 and 14. As such, a mechanical connection between the component 12 and the electronic component 16 may be reinforced compared to electronic devices without interconnects. Furthermore, the interconnects 18 may be manufactured from a material with a good or high thermal and electrical conductivity. A thermal and electrical conductivity between the component 12 and the electronic component 16 may thus be increased compared to electronic devices without interconnects.

FIG. 4 schematically illustrates a cross-sectional side view of a spacer element 400 coated with a coating material. The coated spacer element 400 may be embedded in a joining material (not illustrated). For example, the coated spacer element 400 may correspond to any of the coated spacer elements described in connection with FIGS. 1 and 2.

The coated spacer element 400 may include a spacer element 4 and a coating material 6 coating the spacer element 4. The coating material 6 may include particles 20 embedded in a polymer 22. In the example of FIG. 4, the spacer element 4 is illustrated to have the shape of a ball. In further examples, the shape of the spacer element 4 may be different. Furthermore, the spacer element 4 is illustrated to be completely covered by the polymer 22. In further examples, the spacer element 4 may be only partially covered by the polymer 22. For example, the spacer element 4 may have been coated with the coating material 6 using at least one of a spray coating, a deposition from a gas phase, a deposition from a liquid phase.

The spacer element 4 may be made from at least one of a metal, a polymer, a metal coated polymer. In the example of FIG. 4, a possible metal coating is not illustrated. A dimension (or diameter) of the spacer element 4 may lie in a range from about 10 micrometer to about 80 micrometer, more particular in a range from about 10 micrometer to about 70 micrometer, more particular in a range from about 10 micrometer to about 60 micrometer, more particular in a range from about 10 micrometer to about 50 micrometer, more particular in a range from about 10 micrometer to about 40 micrometer, more particular in a range from about 10 micrometer to about 30 micrometer.

In the example of FIG. 4, the particles 20 are illustrated to have the shape of balls. In further examples, the form of the particles 20 may be different. The particles 20 may be made from a sinter material. For example, a sinter particle 20 may be made from at least one of copper, silver, nickel, palladium, gold, etc. The sinter particles 20 may be nano-sized and may have a dimension lying in a range from about 1 nanometer to about 1000 nanometers, more particular from about 50 nanometers to about 1000 nanometers, more particular from about 50 nanometers to about 800 nanometers, more particular from about 50 nanometers to about 600 nanometers, more particular from about 50 nanometers to about 400 nanometers, more particular from about 50 nanometers to about 200 nanometers. The polymer 22 may include at least one of a polyvinyl alcohol, a polyimide, a polyamide, an acrylate resin, a thermoplast, a thermoset polymer, an epoxy, a high-performance polymer, etc.

FIG. 5 schematically illustrates a cross-sectional side view of a spacer element 500 coated with a coating material. The coated spacer element 500 may be embedded in a joining material (not illustrated). For example, the coated spacer element 500 may correspond to any of the coated spacer elements described in connection with FIGS. 1 and 2, even though the chosen illustration may deviate.

The coated spacer element 500 may include a spacer element 4 that may be coated with particles 20. In the example of FIG. 5, the particles 20 have the form of conical needles. In a further example, the particles 20 may have the form of tubular needles. A material of the particles 20 may be similar to a material of the particles 20 in FIG. 4. In particular, the particles 20 may correspond to silver nano-needles. A needle-shaped particle 20 may have a length or longitudinal extent that may lie in one of the ranges given above with regard to a dimension of the nano-sized sinter particles of FIG. 4.

The particles 20 may be directly arranged on the periphery of the spacer element 4, in particular without an additional embedding material as illustrated in FIG. 4. That is, exposed surface parts of the spacer element 4 may be arranged between the particles 20. In this regard, the particles 20 may cover from about 10% to about 100% of the overall surface of the spacer element 4, more particular from about 30% to about 100%, more particular from about 50% to about 100%, more particular from about 70% to about 100%, more particular from about 90% to about 100%. For example, the spacer element 4 may have been coated with the particles 20 by using a vapor-liquid-solid method.

FIGS. 6A through 6D schematically illustrate respective cross-sectional side views of a method for manufacturing an electronic device 600 in accordance with the disclosure. The method of FIGS. 6A through 6D may be seen as a more detailed implementation of the method of FIGS. 2A and 2B such that details of the method described below may be likewise applied to the method of FIGS. 2A and 2B.

In FIG. 6A, a joining material 10 may be provided over a surface 8 of a component 12. For example, the joining material 10 may be deposited over the surface 8 using a dispensing technique by means of a nozzle 24. In further examples, the joining material 10 may also be deposited using a different technique, for example a squeegeeing technique, a printing technique, etc. The component 12 may be or may include at least one of a diepad, a leadframe, a substrate, a power electronic substrate, a printed circuit board, a chip carrier, a semiconductor package, a metal clip, etc. The surface 8 of the component 12 may at least partly consist of a metal or metal alloy such as e.g. at least one of copper, copper alloys, nickel, iron nickel, aluminum, aluminum alloys, steel, stainless steel, etc.

The joining material 10 may include a base material 2 and spacer elements 4 embedded in the base material 2. For the sake of simplicity, only two spacer elements 4 are illustrated in the example of FIGS. 6A through 6D. The spacer elements 4 may be coated with a coating material 6. The joining material 10 and its components may be similar to the joining materials described in connection with foregoing example such that corresponding comments may also hold true for FIG. 6A. In the example of FIG. 6A, the coated spacer elements 4 are illustrated to have a form as shown in FIG. 4. In further examples, the spacer elements 4 may also be coated with a coating material as shown in FIG. 5.

In FIG. 6B, an electronic component 16 may be arranged over the joining material 10. The electronic component 16 is to be attached or joint to the component 12 by means of the joining material 10 as will be described later on. For example, the electronic component 16 may be arranged by means of a tool 26 configured pick up the electronic component 16 and move it in arbitrary spatial directions. The electronic component 16 may be pressed into the joining material 10 until the joining material 10 covers the lower surface 14 of the electronic component 16. Similar to the surface 8 of the component 12, the lower surface 14 of the electronic component 16 facing the joining material 10 may at least partially consist of a metal or metal alloy. The electronic component 16 may be or may include at least one of a semiconductor die, a passive electronic component, a sensor, an LED, an active electronic component, a semiconductor package.

In FIG. 6C, the joining material 10 may have spread between the component 12 and the electronic component 16 such that the surface 14 of the electronic component 16 may be substantially completely covered by the joining material 10 in one example. After a flow of the joining material 10 may have stopped, the arrangement of FIG. 6C may have reached an equilibrium state. Note that only one layer of the coated spacer elements 4 may be arranged between the component 12 and the electronic component 16 in a horizontal direction. That is, the coated spacer elements 4 may not be stacked over each other in a vertical direction which may result in a constant bondline thickness later on.

In FIG. 6D, interconnects 18 may be formed that may be arranged between the spacer elements 4 and the surfaces 8 and 14, respectively. Depending on the arrangement and the material properties of the coating material 6 and the material of the surfaces 8 and 14, the interconnects 18 may be formed between the spacer elements 4 and the surface 8 of the component 12 or between the surface 14 of the electronic component 16, or both. In particular, the interconnects 18 may represent material-joint interconnects.

The interconnects 18 may be formed on the basis of a sintering process. In this regard, the interconnects 18 may be at least partly formed from the coating material 6 including sinter particles as e.g. described in connection with FIG. 4. Furthermore, the interconnects 18 may be formed based on a melting process in which the coating material 6 is melted that includes a metal having a melting temperature lying in a range from about 150 degrees Celsius to about 1200 degrees Celsius. For example, a metal coating material may have the form of nano-needles as e.g. described in connection with FIG. 5.

The coating material 6 or particles in the coating material 6 (see e.g. FIG. 4) may react with a metal or a metal alloy of the surfaces 8 and 14, respectively, when forming the interconnects 18. The interconnects 18 may therefore also include material from the respective surface 8 and 14. For example, the interconnects 18 may include an intermetallic phase material. In particular, the resulting intermetallic phases may be different from the material of the respective surface 8 and 14. A possible polymer included in the coating material 6 (see e.g. FIG. 4) may at least partly volatilize or escape when forming the interconnects 18. In particular, the polymer may completely volatilize such that no polymer may remain in the formed interconnects 18.

FIGS. 7 and 8 schematically illustrate cross-sectional side views of electronic devices 700 and 800 in accordance with the disclosure. The electronic devices 700 and 800 may be seen as a more specific implementation of the electronic device 300 of FIG. 3. For example, the electronic devices 700 and 800 may be manufactured based on one of the methods of FIGS. 2 and 6.

In the non-limiting example of FIG. 7, the electronic device 700 may include a semiconductor die 16 that may be joint to a chip carrier 12 (e.g. a diepad, a leadframe, a printed circuit board, a power electronic substrate, etc.) by means of a joining material 10. The joining material 10 may include spacer balls 4 and interconnects 18. It is understood that the electronic device 700 may include further components which are not explicitly described for the sake of simplicity. For example, the electronic device 700 may further include an encapsulation material at least partially encapsulating the semiconductor die 16 and/or the chip carrier 12, various coupling elements (e.g. bonding wires, metal clips) electrically coupling to electrodes of the semiconductor die 16, etc. The joining material 10 may form a bondline between the semiconductor die 16 and the chip carrier 12, wherein a thickness of the bondline is substantially constant and substantially equals the dimension of the spacer elements 4.

In the non-limiting example of FIG. 8, the electronic device 800 may include a semiconductor chip 16 arranged over a chip carrier 12. The semiconductor chip 16 may be a power semiconductor chip, for example a power transistor including a gate electrode 28 and source electrode 30 arranged over the top side of the power transistor and a drain electrode 32 arranged over the bottom side of the power transistor. The drain electrode 32 may be electrically coupled to the chip carrier 12 which may be at least partially electrically conductive. A bonding wire 28 may provide an electrical coupling between the gate electrode 28 and a further component (not illustrated). In addition, a metal clip 36 may provide an electrical coupling between the source electrode 30 and a further component (not illustrated).

The metal clip 36 may be joint to the source electrode 30 in accordance with the disclosure by means of a joining material 10. The joining material 10 may include spacer balls 4 and interconnects 18. Note that an attachment of a metal clip as shown in FIG. 8 is not restricted to the specific type of a source electrode, but may also be applied for any other suitable electrode of a semiconductor chip or electronic device. Similar to FIG. 7, the electronic device 800 may include further components which are not explicitly described for the sake of simplicity. For example, the electronic device 800 may include an encapsulation material or further components to which the bonding wire 34 and the metal clip 36 may be electrically coupled.

Devices and methods in accordance with the disclosure may provide the following technical effects which are neither exclusive nor limiting. According to the disclosure a defined and substantially constant bondline thickness may be provided, even though bondline thicknesses may naturally vary due to inevitable procedural inaccuracies. A substantially constant bondline thickness may result in a reduced tilt of a component attached to the joining material. The provision of a defined bondline thickness may result in a defined electrical and/or thermal performance of the electronic device. In addition, bondlines with a minimum defined thickness may provide an improved reliability of the electronic device. Due to a defined bondline thickness, a creepage of the joining material along sidewalls of the electronic component attached to the joining material may be reduced. A defined bondline thickness may reduce a spread out of the joining material on the component to which the electronic object is attached. Such reduced spread out may provide an increase of available area on the component, for example for further electronic objects to be attached. Due to the provision of a defined bondline thickness, there may be less adjustment of process parameters required during the attachment of the electronic component. Less adjustment required may result in an increased UPH (Units per Hour) value during production of the electronic devices. According to the disclosure a bond pressure when attaching an electronic object to a joining material may be reduced.

As employed in this specification, the terms “connected”, “coupled”, “electrically connected” and/or “electrically coupled” may not necessarily mean that elements must be directly connected or coupled together. Intervening elements may be provided between the “connected”, “coupled”, “electrically connected” or “electrically coupled” elements.

Further, the word “over” used with regard to e.g. a material layer formed or located “over” a surface of an object may be used herein to mean that the material layer may be located (e.g. formed, deposited, etc.) “directly on”, e.g. in direct contact with, the implied surface. The word “over” used with regard to e.g. a material layer formed or located “over” a surface may also be used herein to mean that the material layer may be located (e.g. formed, deposited, etc.) “indirectly on” the implied surface with e.g. one or more additional layers being arranged between the implied surface and the material layer.

Furthermore, to the extent that the terms “having”, “containing”, “including”, “with” or variants thereof are used in either the detailed description or the claims, such terms are intended to be inclusive in a manner similar to the term “comprising”. That is, as used herein, the terms “having”, “containing”, “including”, “with”, “comprising” and the like are open-ended terms that indicate the presence of stated elements or features, but do not preclude additional elements or features. The articles “a”, “an” and “the” are intended to include the plural as well as the singular, unless the context clearly indicates otherwise.

Moreover, the word “exemplary” is used herein to mean serving as an example, instance, or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form. Also, at least one of A and B or the like generally means A or B or both A and B.

Devices and methods for manufacturing devices are described herein. Comments made in connection with a described device may also hold true for a corresponding method and vice versa. For example, if a specific component of a device is described, a corresponding method for manufacturing the device may include an act of providing the component in a suitable manner, even if such act is not explicitly described or illustrated in the figures. In addition, the features of the various exemplary aspects described herein may be combined with each other, unless specifically noted otherwise.

Although the disclosure has been shown and described with respect to one or more implementations, equivalent alterations and modifications will occur to others skilled in the art based at least in part upon a reading and understanding of this specification and the annexed drawings. The disclosure includes all such modifications and alterations and is limited only by the concept of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application.

What is claimed is:

1. A method, comprising:
providing a joining material between a surface of a component and a surface of an electronic component, a plurality of spacer elements being embedded in the joining material, the spacer elements being coated with a coating material, the coating material comprising sinter particles, a dimension of the sinter particles being greater than 1 nanometer and smaller than 1000 nanometers; and
forming interconnects from the coating material, the interconnects being arranged between the spacer elements and the surface of the component and between the spacer elements and the surface of the electronic component.

2. The method of claim 1, wherein forming the interconnects comprises sintering the coating material.

3. The method of claim 1, wherein the coating material comprises a metal having a melting temperature in a range from about 150 degrees Celsius to about 1200 degrees Celsius, and wherein the metal is configured to react with a material of at least one of the surface of the component and the surface of the electronic component when forming the interconnects.

4. The method of claim 1, wherein the coating material comprises a polymer covering a surface of the spacer elements, and wherein the sinter particles are embedded in the polymer.

5. The method of claim 1, wherein the sinter particles are arranged on surfaces of the spacer elements, and wherein the sinter particles cover from about 10% to about 100% of an overall surface of the spacer elements.

6. The method of claim 1, wherein the coating material comprises first sinter particles and the joining material comprises second sinter particles.

7. The method of claim 6, wherein a dimension of the first sinter particles is smaller than a dimension of the second sinter particles.

8. The method of claim 6, wherein a density of the first sinter particles in the coating material is greater than a density of the second sinter particles in the joining material.

9. The method of claim 6, wherein:
a dimension of the first sinter particles is smaller than a dimension of the second sinter particles; and
a density of the first sinter particles in the coating material is greater than a density of the second sinter particles in the joining material.

10. The method of claim 1, wherein the joining material comprises at least one of a metal paste, a sinter paste, a solder paste, a nano paste, an adhesive material, and an electrically conductive adhesive.

11. The method of claim 1, further comprising:
coating the spacer elements with the coating material, wherein coating the spacer elements comprises at least one of a spray coating, a deposition from a gas phase, a deposition from a liquid phase, and a vapor-liquid-solid method.

12. The method of claim 1, wherein the dimension of the sinter particles is greater than 50 nanometers and smaller than 200 nanometers.

13. The method of claim 1, wherein a dimension of the spacer elements is in a range from 10 micrometers to 30.

14. The method of claim 1, wherein the sinter particles are arranged on a surface of the spacer elements without an additional embedding material.

15. The method of claim 1, wherein the sinter particles cover 90% to 100% of an overall surface of the spacer elements.

16. The method of claim 1, wherein providing the joining material comprises:
coating the spacer elements with the coating; and
embedding the spacer elements with the coating in a base material.

17. The method of claim 16, wherein the base material is or comprises at least one of a metal paste, a sinter paste, a solder paste, and a nano paste.
